(19) United States
(12) Patent Application Publication
(10) Pub. No.: US 2015/0310933 A1
(43) Pub. Date: Oct. 29, 2015

(54) Configurable Test Address And Data Generation For Multimode Memory Built-In Self-Testing

(71) Applicant: Lattice Semiconductor Corporation, Hillsboro, OR (US)

(72) Inventors: Naveen Purushotham, Portland, OR (US); Kanad Chakraborty, Portland, OR (US); Daniel Ratchen, Portland, OR (US)

(21) Appl. No.: 14/482,001

(22) Filed: Sep. 10, 2014

Related U.S. Application Data
(60) Provisional application No. 61/984,203, filed on Apr. 25, 2014.

(51) Int. Cl. G11C 29/38; G11C 29/36; G11C 29/18

(52) U.S. Cl. CPC G11C 29/38; G11C 29/18; G11C 29/36

(57) ABSTRACT

In certain embodiment, built-in self-test (BIST) circuitry for multiport memory comprises a configurable address generator and a configurable data generator. The configurable address generator can be configured to concurrently generate first and second logical memory addresses corresponding to physically neighboring first and second memory cells of the multiport memory for any selected memory mode of a plurality of available memory modes having different column-multiplexing schemes. The configurable data generator can be configured to concurrently generate two sets of data for the selected memory mode, such that (i) the first set of data is written into and read from the multiport memory via a first memory port using the first logical memory address and (ii) the second set of data is written into and read from the multiport memory via a second memory port using the second logical memory address. The BIST circuitry enables efficient, physically aware built-in self-testing.

### CROSS-REFERENCE TO RELATED APPLICATIONS

This application claims the benefit of the filing date of U.S. provisional application No. 61/984,203, filed on Apr. 25, 2014, the teachings of which are incorporated herein by reference in their entirety.

### BACKGROUND

1. Field of the Invention

The present invention relates to electronics and, more specifically but not exclusively, to built-in self-test (BIST) schemes for embedded memory in integrated circuits.

2. Description of the Related Art

This section introduces aspects that may help facilitate a better understanding of the invention. Accordingly, the statements of this section are to be read in this light and are not to be understood as admissions about what is prior art or what is not prior art.

Shrinking geometries have made exhaustive testing of embedded memories imperative. Embedded RAMs (random-access memories) use a variety of test algorithms and memory-stress conditions to provide high fault coverage for stuck-at, transition, coupling, read- and write-disturb, and neighborhood pattern-sensitive faults. Built-in self-test (BIST) for embedded memories is widely adopted as an alternative methodology to automated test equipment (ATE)-based testing because of advantages such as a) ensuring at-speed testing irrespective of ATE capability, b) reduced test vector memory on the ATE, c) reduced pin usage, and d) reduced test time. On the other hand, the disadvantages of BIST circuitry are area overhead, design effort, and performance penalty during normal operation due to circuit isolation multiplexers in the BIST collar. In general, the benefits of built-in self-testing outweigh its disadvantages, especially for FPGAs (field-programmable gate arrays) where BIST circuits can be implemented as soft logic on programmable fabric, which has essentially no area overhead or performance penalty.

Several memory BIST architectures have been developed and used over the years. Some of the popular ones are simple counter/linear feedback shift register (LFSR)-based BIST, programmable finite state machine (FSM)-based BIST, microcode-based BIST, and non-programmable BIST.

Conventional integrated circuits having embedded memories can support a variety of different memory modes in which the physical address space of the memory is mapped into different logical address spaces for different memory modes. In general, two consecutive memory addresses in a given logical address space might not correspond to two adjacent memory cells in the actual physical memory. In order to provide BIST schemes for testing neighborhood pattern-sensitive faults in such conventional integrated circuits, special circuitry is typically provided for each different memory mode to generate memory addresses in the corresponding logical address space that correspond to neighboring memory cells in the actual physical memory.

### BRIEF DESCRIPTION OF THE DRAWINGS

Other embodiments of the invention will become more fully apparent from the following detailed description, the appended claims, and the accompanying drawings in which like reference numerals identify similar or identical elements.

FIG. 1 represents the physical layout of the neighboring cell space with four possible victim cells (V1, V2, V3, V4) for an aggressor cell (A);

FIG. 2 shows a block diagram of an exemplary implementation for microcode-based built-in self-testing of an embedded RAM memory;

FIGS. 3 and 4 respectively show Tables 1 and 2, which present the bit values for the eleven control words for a portion of the modified March LR algorithm;

FIG. 5 shows an exemplary block diagram of the address generator of FIG. 2;

FIG. 6 shows Table 3, which presents exemplary settings for control word bits CW[3:5], where Port A accesses Aggressor Cell A and Port B can access one of five possible cells—the Victim Cells V1, V2, V3, V4 or Aggressor Cell A;

FIG. 7 shows an exemplary block diagram of the data generator of FIG. 2;

FIG. 8 illustrates an exemplary memory topology for a “1024×18” memory mode having a data width of 18 bits and a physical memory having 4-bit column multiplexing and interleaving;

FIG. 9 illustrates an exemplary memory topology for a “2048×9” memory mode having a data width of 9 bits and a physical memory having 8-bit column multiplexing and interleaving;

FIGS. 10 and 11 illustrate in table form the different bit values of the register of FIG. 7 for a checkerboard pattern and an inverse checkerboard pattern, respectively;

FIG. 12 illustrates in table form data for the register of FIG. 7 written in associated memory addresses generated in lockstep by the address generator of FIG. 5;

FIG. 13 shows Table 4, which presents exemplary settings for control word bits CW[11:12], where Port A accesses Aggressor Cell A and Port B is one of the Victims V1 or V2; and

FIGS. 14-17 illustrate in table form the different bit values of register 702 of FIG. 7 for a row stripe pattern, an inverse row stripe pattern, a column stripe pattern, and an inverse column stripe pattern, respectively.

### DETAILED DESCRIPTION

This specification describes configurable address and data generation for a microcode-based BIST architecture that enables physical-topology-aware multiport memory testing. Using this approach, the aggressor and victim addresses needed to exercise topologically (i.e., physically) neighboring cells for cross-port and single-port coupling faults can be generated with programmable BIST circuitry implemented on FPGA fabric or using hard logic gates. Data generation takes advantage of the knowledge of column multiplexing and interleaving of bits in physical maps of memories and generates various data backgrounds with simple multiplexing and counter-based logic. Column multiplexing is defined as selecting a small set of output bits from a larger set of columns. For example, if a (512×16) RAM array is folded into 128 rows by 64 columns in the physical layout, then we need 16 4:1 column multiplexers to select 16 output bits from the 64 columns. Sometimes, the degree of column multiplexing can change from one mode of memory operation to another.

Interleaving is defined as spreading the bits of a logical memory word evenly across the physical memory word, so as to improve reliability by minimizing the likelihood of uncorrectable multiple-bit soft errors in a logical word. It is a commonly used technique to improve reliability for wide memory blocks, and may or may not be used for relatively small embedded RAM blocks. The configurable address generation and data generation described in this specification works whether or not interleaving is employed. Previously published programmable memory BIST approaches have focused on non-topological address and data generation to exercise coupling faults in single- and multi-port embedded RAMs.

The present approach is truly flexible by completely converting every memory-control operation in published algorithms into microcode, and adding cross-port capability using dynamic address generation for physical neighborhoods, and allowing dynamic loading of a variety of data background patterns. Aggressor and victim cell physical address generation essential for non-classical faults can be controlled dynamically.

### Physically Aware BIST Architecture

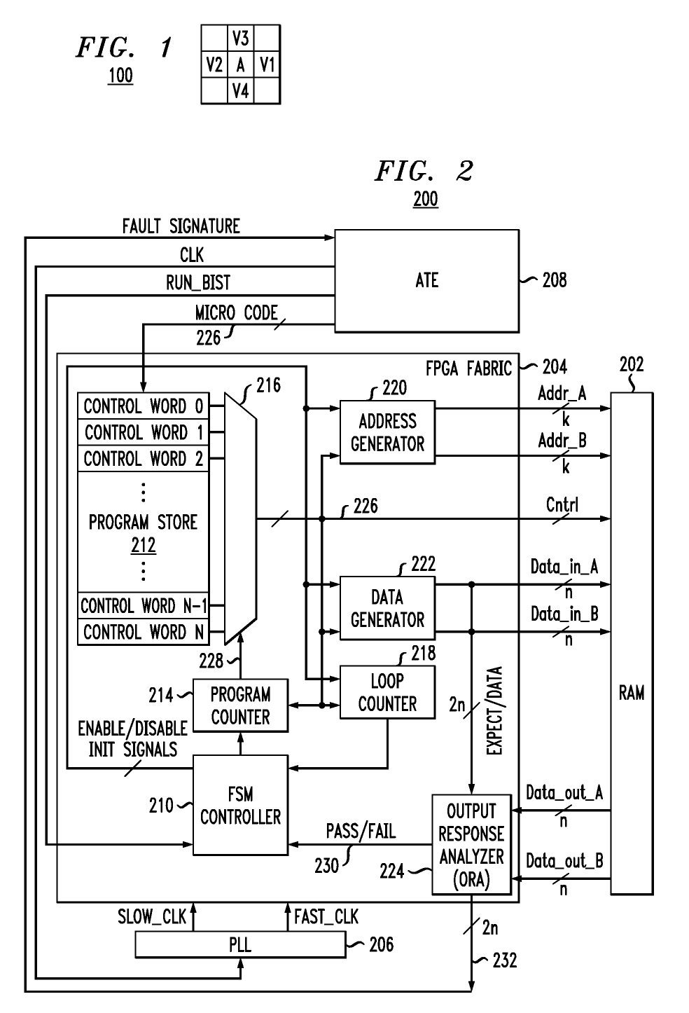

FIG. 1 represents the physical layout of the neighboring cell space 100 for an aggressor cell A. Certain types of BIST memory testing, such as BIST for cross-port algorithms, are based on detecting the effects that aggressor cells have on their adjacent neighboring cells. FIG. 1 shows the four possible victim cells V1-V4 for aggressor cell A, where:
Victim V1 is in the right adjacent column and the same row as aggressor A;
Victim V2 is in the left adjacent column and the same row as aggressor A;
Victim V3 is in the same column and the top adjacent row as aggressor A; and
Victim V4 is in the same column and the bottom adjacent row as aggressor A.

Built-in self-testing for cross-port algorithms have unique requirements for address and data generation. The address generator simultaneously generates the logical addresses for the aggressor and for one of the aggressor's physically neighboring victims for both ports of a dual-port memory on a clock-by-clock basis. Note that the data generation must generate data for the aggressor's physical neighborhood, not necessarily for the aggressor's logical neighborhood, which may be different from the physical neighborhood depending on the particular memory mode. Common data patterns (aka backgrounds) used for cross-port BIST algorithms include:
Checkerboard/Inverse checkerboard;
Row stripe/Inverse row stripe;
Column stripe/Inverse column stripe; and
All 0s/All 1s.
   Additionally, data generation can also include expected data generation. If the address and data generators meet these requirements they can be fused into any microcode-based BIST architecture.

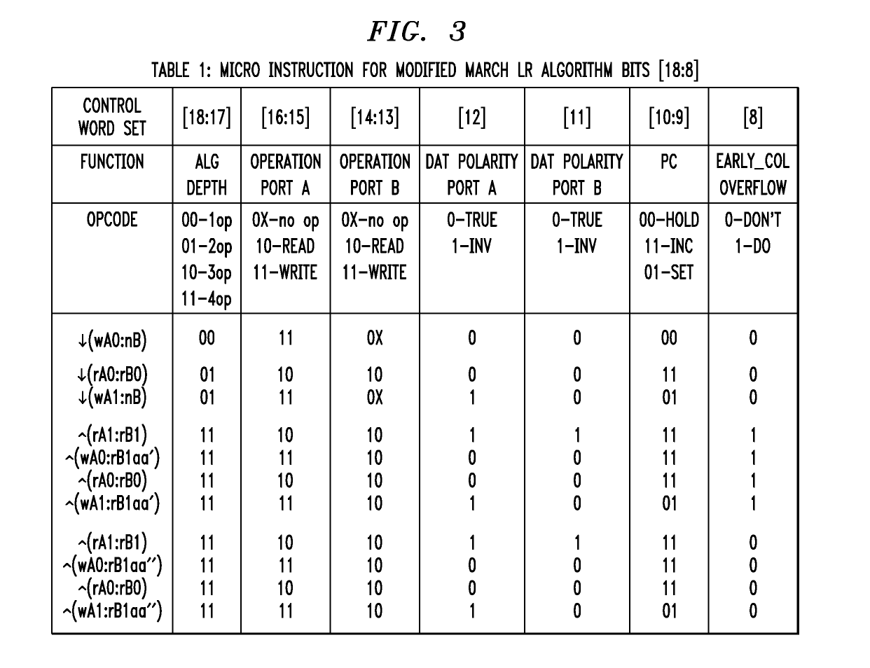

FIG. 2 shows a block diagram of an exemplary implementation 200 for microcode-based built-in self-testing of embedded RAM memory 202. As shown in FIG. 2, implementation 200 includes memory 202, fabric 204, and phase-locked loop (PLL) 206, all of which are implemented on a field-programmable gate array (FPGA), as well as off-chip automated test equipment (ATE) 208. ATE 208 provides overall control of the memory testing, while finite state machine (FSM) controller 210, implemented in FPGA fabric 204, provides on-chip control of the built-in self-testing.

Also implemented in FPGA fabric 204 are program store 212, program counter 214, multiplexer 216, loop counter 218, address generator 220, data generator 222, and output response analyzer 224.

Functionally, ATE 208 provides an off-chip clock signal CLK to on-chip PLL 206, which generates a slow clock signal SLOW_CLK and a fast clock signal FAST_CLK, both of which are used in built-in self-testing. Note that FAST_CLK is faster than SLOW_CLK, which, depending on the particular implementation, may be faster, slower, or the same speed as off-chip clock CLK. ATE 208 also provides a set of N 19-bit microcode control words 226 for storage into on-chip program store 212. As described further below, these control words 226 control the individual steps of built-in self-testing.

Program counter 214 increments the multiplexer selection signal 228 for multiplexer 216 to sequentially select and present the next 19-bit control word 226 from program store 212 as the current control word. Different portions (i.e., one or more bits) of the current control word 226 are presented to program counter 214, loop counter 218, address generator 220, and data generator 222. Note that each control word 226 corresponds to a single memory operation on each port of the memory. Thus, each given step in a BIST algorithm defined by a single control word 226 may correspond to two memory operations for a dual-port RAM.

In particular, program counter 214 receives a portion of the current control word 226 and determines when to update multiplexer selection signal 228 to select the next control word 226 in program store 212.

Loop counter 218 receives a portion of the current control word 226 and generates a status signal for the FSM controller 210, which in turn will move the program counter 214 to the next march element (described later as a set of control words 226 that will be looped over until all the addresses are exhausted in a particular direction).

Based on a portion of the current control word 226, address generator 220 simultaneously generates two k-bit RAM address values: Addr_A for Port A of dual-port memory 202 and Addr_B for Port B of memory 202. At the same time, based on a portion of the current control word 226, data generator 222 simultaneously generates two corresponding n-bit incoming (i.e., write) data values: Data_In_A to be stored in memory 202 at address Addr_A and Data_In_B to be stored in memory 202 at address Addr_B. Data_In_A is valid incoming data only if Port A is performing a write operation. In a “read” mode or a “no-operation” mode, this value is ignored. The same is true for Data_In_B and Port B.

Those same two n-bit data values are provided in parallel to output response analyzer (ORA) 224 as 2n-bit expected data Expect_Data. Analyzer 224 subsequently receives two n-bit outgoing (i.e., read) data values Data_Out_A and Data_Out_B read from memory 202 at the same two addresses Addr_A and Addr_B and performs a bit-by-bit comparison of those two read data values to the two expected data values, respectively, to determine if there are any bit differences, which would indicate a BIST error. The expected data is valid only if the corresponding port is performing a read operation. If the port is in a “write” mode or a “no-operation” mode, then there is the possibility of generating a false fail. In that case, the BIST error flag is ignored. Analyzer 224 provides feedback both to on-chip FSM controller 210 in the form of a binary pass/fail signal 230 and to off-chip ATE 208 in the form of two n-bit fault signatures 232 indicating the locations of bit differences, if any.

The present approach uses physical topology information (e.g., address scrambling of row and column decoders, column multiplexing and interleaving) of the memory to generate addresses and data for both ports of memory 202. The design of aggressor and victim address generator 220 is presented for physically-aware programmable multi-port memory built-in self-testing, in which address generator 220 generates addresses in lockstep with data generator 222 based on information from microcode and physical topology of the memory. Configurable address generator 220 generates addresses for both ports (Port A and Port B) of the embedded RAM 202. The aggressor address (e.g., Addr_A) is used to generate the victim address (e.g., Addr_B) based on physical neighborhood information. Previously, aggressor and victim addresses were generated independently [see Refs. 3, 4, 5, and 14].

The design of a configurable data generator 222, which runs in lockstep with address generator 220 and generates different data backgrounds based on 8-bit programmable register data, is presented. Data generator 222 generates both write data (i.e., Data_In_A and Data_In_B) and expected data (i.e., Expect_Data) for both ports of the memory. The address and data generators can be fused into a standard microcode-based BIST with some extension to its instruction set.

The microcode in the form of a set of up to N 19-bit control words 226 can be loaded dynamically into the BIST architecture using ATE 208. The microcode can encode many published cross-port march algorithms. A march test involves the application of a finite number of read and write operations to each memory cell before proceeding to the next cell, and traversing the memory only along a certain predetermined address sequence or its reverse. Each 19-bit control word 226 stores a single operation of the march algorithm and supports control for both ports of the memory 202. Each control word 226 has embedded within itself physical topology data needed for address and data generation. Each bit of the control word is discussed below in the context of the modified March LR algorithm in order to further illustrate the instruction set.

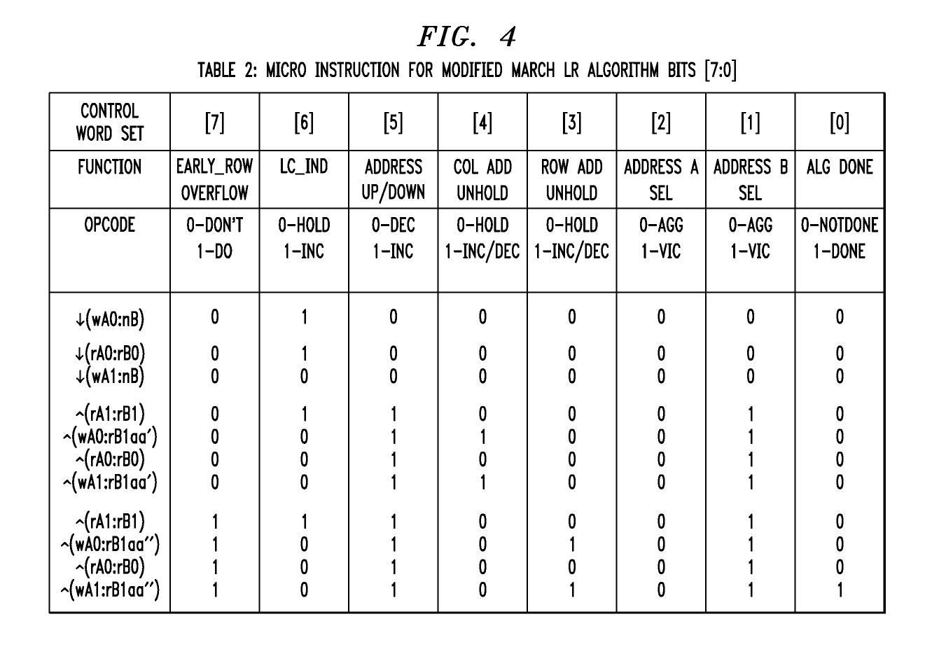

FIG. 3 shows Table 1, which presents the values for bits [8:18] for the eleven control words 226 for the modified March LR algorithm, while FIG. 4 shows Table 2, which presents for bits [7:0] for those same eleven control words 226. Each control word is an operation. A group of one or more march operations performed in a single march of all the addresses is a march element. For example, in FIG. 3, each row corresponds to a different march operation, where Row 1 corresponds to a first march element, Rows 2-3 correspond to a second march element, Rows 4-7 correspond to a third march element, and Rows 8-11 correspond to a fourth march element.

The “Control Word Set” column of Tables 1 and 2 identifies the eleven operations of the modified March LR algorithm. The address order is given by the {↓, ̂} signs, where the sign “↓” refers to address sequencing in descending order, while the sign “̂” refers to address sequencing in ascending order. The codes “nA” and “nB” indicate no operation being performed on port A and port B, respectively. The code “wA0” indicates that a write operation be performed for port A using the chosen data background, while the code “wA1” indicates that a write operation be performed for port A using the inverse of the chosen data background, and similarly for the codes “wB0” and “wB1” for port B. The analogous read operations are indicated using the codes “rA0”, “rA1”, “rB0”, and “rB1”. For example, a march operation may involve writing a checkerboard (ckbd) pattern on an address during the first run through the addresses. This will involve the data register in the data generator containing the ckbd pattern. However, the subsequent march operation may involve writing an inverse ckbd pattern on the same address and reading the previously written ckbd pattern from the adjacent address before writing the inverse ckbd pattern on it in the next cycle.

The codes aa′, aa″, ab′, and ab″ refer to the neighboring address cells as follows:
aa′=adjacent column and same row as address aa
aa″=adjacent row and same column as address aa
ab′=adjacent column and same row as address ab
ab″=adjacent row and same column as address ab
   Referring to FIG. 1, if cell A is referred to as aa, then cell V1 is aa′ and cell V3 is a″. Similarly, if cell A is referred to as ab, then cell V2 is ab′ and cell V4 is ab″. These codes help illustrate the modified March LR algorithm.

The “ALG Depth” field (i.e., control word bits CW[18:17]) stores information regarding the number of operations (i.e., 1-4) in the current march element. The ALG Depth field is applied to address generator 220 and loop counter 218.

Each of the two “Operation” fields (i.e., CW[16:15] for Port A and CW[14:13] for Port B) stores information regarding the memory operation (i.e., write, read, or no operation) that is to be performed for the particular march operation on the associated port. The most-significant bit (MSB) for the Operation field can also be used as a clock enable signal for the associated port, while the least-significant bit (LSB) can be used as a write enable for the associated port. The two Operation fields are applied to memory 202.

Each of the two “Dat Polarity” fields (i.e., CW[12] for Port A and CW[11] for Port B) is applied to data generator 222 to indicate whether or not the background data is to be inverted for the associated port.

The “PC” field (i.e., CW[10:9]) is applied to program counter 214 to control its operation. When the PC field indicates “hold,” program counter 214 maintains the current value of multiplexer selection signal 228 to retain the current control word 226. When the PC field indicates “increment,” program counter 214 increments the value of multiplexer selection signal 228 to select the next control word 226 in program store 212 as the new current control word for the next cycle. When the PC field indicates “set,” program counter 214 sets the value of multiplexer selection signal 228 to a default value to select the corresponding control word 226 in program store 212 as the new current control word for the next cycle. The default value is stored in a register and is the starting position of the current march element in the program store 212.

The “Early_Col Overflow” field (i.e., CW[8]) and the “Early_Row Overflow” field (i.e., CW[7]) are applied to address generator 220 to signal the last column/row of the physical memory map in order to prevent address generator 220 from generating adjacent victim addresses that do not exist.

The “LC_IND” field (i.e., CW[6]) is applied to loop counter 218 as an enable signal. The loop counter keeps track of the march element loop, because some march elements can have multiple operations being performed on the same address before moving to the next address. For example, the control word (r0w1r1) has a loop consisting of three operations: a read operation, followed by a write operation, followed by another read operation. Loop counter 218 keeps track of the march elements and generates a status signal that moves FSM controller 210 into an initialization state which will set the initialization values for address generator 220 and the program counter 214, which controls the control word 226 for the next cycle. When the LC_IND field indicates “hold,” loop counter 218 maintains the current loop number. When the LC_IND field indicates “inc,” loop counter 218 increments the current loop number. The LC_IND field is also applied to address generator 220, which may need to hold the addresses constant until the current loop has finished.

The “Address UP/Down” field (i.e., CW[5]) is applied to address generator 220 to control whether the address values are to decrease or increase for the current march element.

The “Col Add Unhold” field (i.e., CW[4]) and the “Row Add Unhold” field (i.e., CW[3]) are applied to address generator 220 to unhold (i.e., release) the column/row address generation for a particular cycle and overwrite the restriction imposed by the loop counter. Such cases arise in cross-port algorithms where there is a need to apply addresses in a non-linear fashion.

The “Address A Set” field (i.e., CW[2]) and the “Address B Set” field (i.e., CW[1]) are applied to address generator 220 to indicate whether Port A or Port B corresponds to the aggressor or the victim. Note that there are cases where neither cell is an aggressor or a victim. For example, in a read operation on the same address from both ports, the two address will be the same.

The “Alg Done” field (i.e., CW[0]) is applied to FSM controller 210 to indicate the end of the current march algorithm.

### Configurable Address Generator

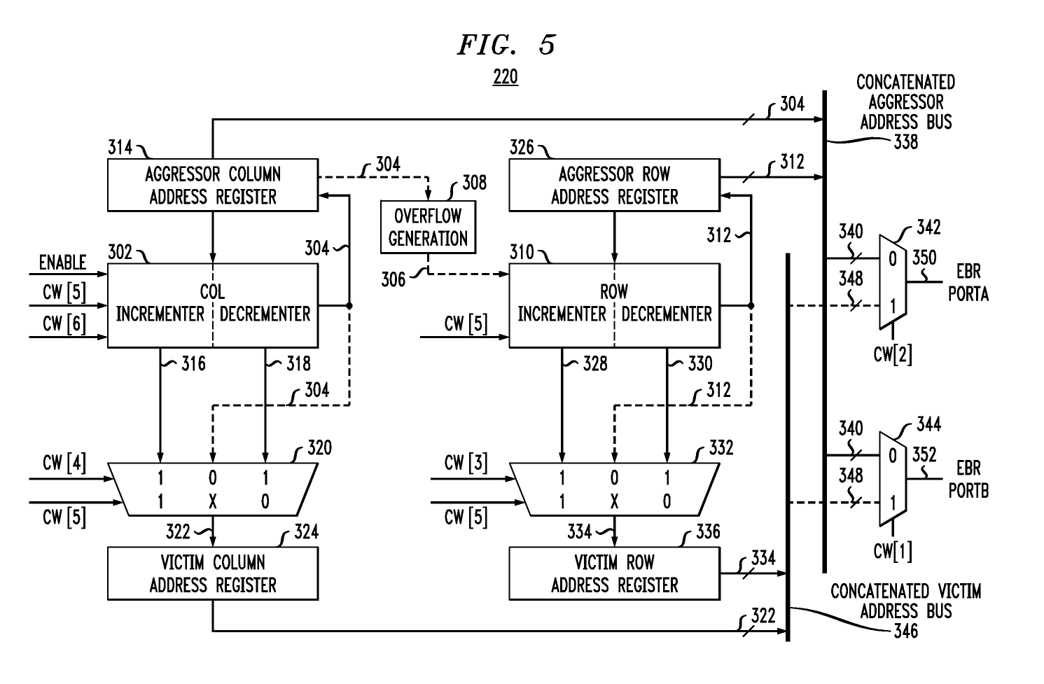

FIG. 5 shows an exemplary block diagram of address generator 220 of FIG. 2. Address generator 220 simultaneously generates the column and row addresses for both the aggressor and victim cells based on the current control word 226.

In particular, FSM controller 210 generates an initialization signal that initializes the column and row addresses based on the addressing direction of the march element defined by the control word 226. The “Address Up/Down” field (i.e., CW[5]) and the “LC_IND” field (i.e., CW[6]) are applied to column incrementer/decrementer 302. Column incrementer/decrementer 302 increments, decrements, and holds the corresponding column address value 304 depending on CW[6], which acts as an tick enable, and CW[5], which controls if it's an increment or a decrement. The “Address Up/Down” field (i.e., CW[5]) and column overflow signal 306 generated by overflow generation module 308 are applied to row incrementer/decrementer 310. Row incrementer/decrementer 310 increments, decrements, and holds the corresponding row address value 312 depending on column overflow signal 306, which acts as a tick enable, and CW[5], which controls if it's an increment or a decrement.

The column address value 304 is stored in aggressor column address register 314 as the column address value for the current aggressor cell. In addition, the column address value 304 along with the corresponding incremented and decremented column address values 316 and 318 are applied to 3×1 column multiplexer 320, which outputs and stores one of those three applied column address values as the column address value 322 for the current victim cell in victim column address register 324 based on the current control word bits CW[4] and CW[5], which determines whether the current victim cell is in the same column as or in the column to the left or to the right of the current aggressor cell.

Similarly, the row address value 312 is stored in aggressor row address register 326 as the row address value for the current aggressor cell. In addition, the row address value 312 along with the corresponding incremented and decremented row address values 328 and 330 are applied to 3×1 row multiplexer 332, which outputs and stores one of those three applied row address values as the row address value 334 for the current victim cell in victim row address register 336 based on the current control word bits CW[3] and CW[5], which determines whether the current victim cell is in the same row as or in the row above or below the current aggressor cell.

The aggressor column and row address values 304 and 312 stored in aggressor registers 314 and 326 are concatenated in concatenated aggressor address bus 338 and applied as aggressor memory address 340 to the first inputs of 2×1 Port A multiplexer 342 and 2×1 Port B multiplexer 344. Similarly, the victim column and row address values 322 and 334 stored in victim registers 324 and 336 are concatenated in concatenated victim address bus 346 and applied as aggressor memory address 348 to the second inputs of Port A multiplexer 342 and Port B multiplexer 344.

Port A multiplexer 342 outputs one of the aggressor and victim memory addresses 340 and 348 as the memory address 350 applied to Port A of memory 202 based on the current control word bit CW[2], while Port B multiplexer 344 outputs one of those same two memory addresses as the memory address 352 applied to Port B of memory 202 based on the current control word bit CW[1].

Overflow generation module 308 receives the current aggressor column address value 304 from register 314 and detects basic overflow situations. Primarily, module 308 serves as a row counter enable generator, wherein it generates an enable signal 306 that increments or decrements the row incrementer/decrementer 310 as the column reaches the maximum or minimum position based on the addressing direction to continue to the next possible physical address. Additional logic in address generator 220 (not shown in FIG. 5 for clarity) receives information from CW[7] and CW[8] to handle other overflow conditions (pertaining to victim address). In cases where the aggressor cell is the left-most column, there is no victim cell to the left of the aggressor, and there is a need to update the row address before the aggressor reaches this cell. For example, if processing is moving towards the “max” column address, then the row update should occur at “max−1”. The right-most aggressor cell is also handled in the same way. Also, this case occurs for row counters where the top-most and bottom-most aggressor cells are not operated on, due to the lack of victim addresses on top and bottom, respectively. In such cases, the program counter 214 is updated to move to the next march element.

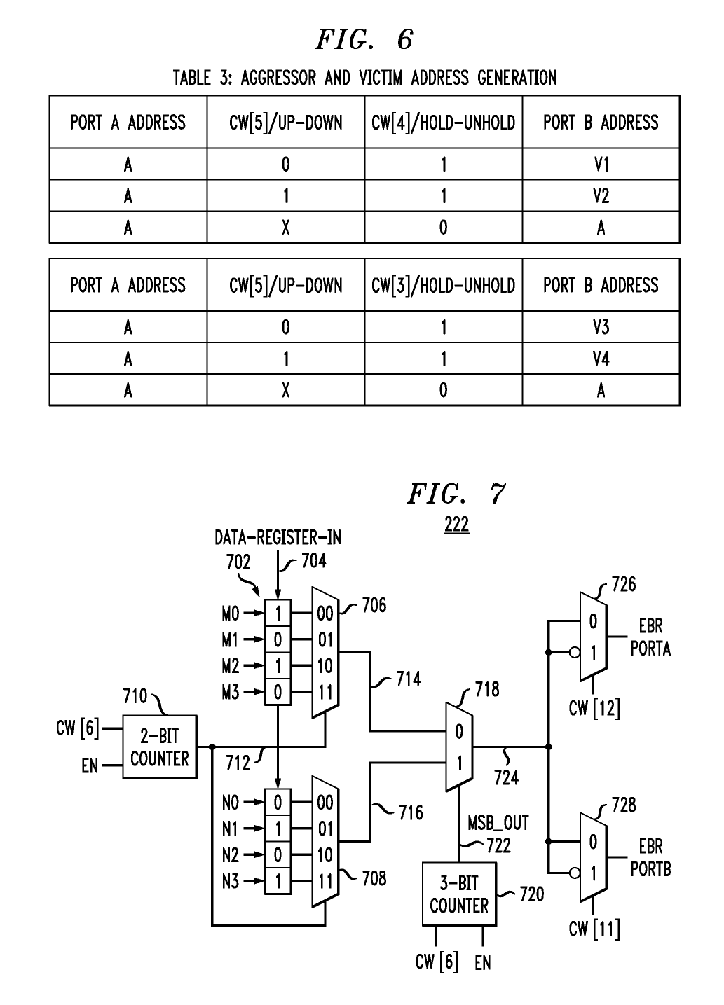

FIG. 6 shows Table 3, which presents exemplary settings for control word bits CW[3:5], where Port A accesses Aggressor Cell A and Port B can possibly access one of the Victim Cells V1, V2, V3, V4 or Aggressor Cell A. Note that Port A and Port B are accessed concurrently.

The configurability of the row and column counters to point to aggressor and victim cells depending on the degree of column multiplexing for a mode is what causes built-in self-testing of the present invention to be physical-layout aware. Depending on the mode selected, the maximum row and column counts would change, and the logical addresses of aggressors and victims would map directly to physical addresses, without the need for any address translation. Physical addresses are not generated. Rather, logical addresses are generated based on knowledge of the memory mode of operation (i.e., interleaving and the degree of column multiplexing) and configuring the address counters to generate logical addresses that map to the physical neighborhood. The physical neighborhood is constant while the logical neighborhood is mode dependent. The size of the column multiplexing of the physical layout dictates when the column counter enables the row counter.

The limits of the victim row and column addresses are generated from aggressor addresses based on the mode and boundary conditions imposed by the physical map. If there are no victim addresses on the boundaries of the column multiplexed layout, then the counters re-initialize themselves.

### Configurable Data Generator

FIG. 7 shows an exemplary block diagram of data generator 222 of FIG. 2. Data generator 222 runs in lockstep with address generator 220 to generate respective write data Data_In_A and Data_In_B for Port A and Port B of memory 202, which is also the expected data Expect_Data applied to output response analyzer 224. The exemplary implementation shown in FIG. 7 uses a 4-bit column-multiplexed memory to generate data backgrounds based on 8-bit data. Note that alternative implementations may employ column multiplexing having other lengths.

In particular, 8-bit data register 702 receives a set of binary background data 704. The exemplary values shown in FIG. 7 correspond to a checkerboard pattern. In a checkerboard pattern, if an aggressor cell has a value of 1, then the corresponding victim cell has a value of 0, and vice versa, where the overall background pattern forms a checkerboard of alternating 1s and 0s. Note that the eight bits of data register 702 are respectively labeled M0-M3 and N0-N3. Bits M0-M3 are applied to 4×1 multiplexer 706, while bits N0-N3 are applied to 4×1 multiplexer 708.

2-bit counter 710 generates 2-bit multiplexer selection signal 712, which controls the selection of the respective 1-bit outputs 714 and 716 from multiplexers 706 and 708, which outputs are applied to 2×1 multiplexer 718. 3-bit counter 720 generates 1-bit multiplexer selection signal 722, which is the MSB of its internal 3-bit counter and controls the selection of the 1-bit output 724 from multiplexer 718. 1-bit output 724 and its complement are both applied (i) to 2×1 multiplexer 726, which outputs the current bit of Data_In_A for Port A of memory 202 based on current control word bit CW[12] and (ii) to 2×1 multiplexer 728, which outputs the current bit of Data_In_B for Port B of memory 202 based on current control word bit CW[11], where bits CW[12] and CW[11] control the polarity of the data.

When current control word bit CW[6] and enable signal EN are both one, (i) counter 710 increments multiplexer selection signal 712 and (ii) counter 720 increments its internal counter and if appropriate updates multiplexer selection signal 722. Otherwise, counters 710 and 720 maintain their previous states. Control word bit CW[6] maintains the states of the two counters until all of the operations of the current march element are completed.

At every increment of counter 710, the next input of each of multiplexers 706 and 708 is selected. Since multiplexer selection signal 722 is the MSB of its internal 3-bit counter, the first input to multiplexer 718 is selected for four consecutive increments of counter 720, and then the second input to multiplexer 718 is selected for the next four consecutive increments of counter 720, and that sequence is continually repeated. In this way, all eight bits of data register 702 are sequentially selected for each set of eight increments of the counters. Note that, if, for example, 8-bit column multiplexing were employed instead of the 4-bit column multiplexing of FIG. 7, then 2-bit counter 710 would be replaced by a 3-bit counter, and 3-bit counter 720 would be replaced by a 4-bit counter.

Data generator 222 is designed based on the column multiplexing of the physical memory map. Data generator 222 can generate various types of physical background data (e.g., scan 0/1 checkerboard, row stripe, column stripe) by writing all 1s and all 0s to a particular logical address. For example, if physical checkerboard data is to be written to the memory, then knowledge of the column multiplexing used in the physical topology enables the data generator 222 to apply the appropriate data. To further illustrate this, consider FIG. 8, which corresponds to an exemplary memory topology with column multiplexing of 4, data width of 18, and scrambled addressing. In clock cycle 1, data bit 0 is written to address 0 (i.e., all 18 bits of address 0 are written with bit 0, which corresponds to data<0>data<1> etc. to data<17>; hence, writing all 0's to that logical address). In clock cycle 2, data value 1 is written to address 2 (i.e., all 18 bits of address 2 are written with value 0, which corresponds to data<0>data<1> etc. to data<17>; hence, writing all 1's to that logical address). However, address 0 and address 2, which are physically adjacent, have a checkerboard neighborhood as a result. Note that all-0/all-1 logical data may be generated to produce a physical checkerboard pattern.

The control words are actually agnostic of the physical layout, meaning, even if the physical layout changes for the memory, control instructions for the modified March LR algorithm will be the same. However, the configurable sizes of the address counters, data registers, loop counters, and re-initialization of the victim addresses at boundary conditions will change. Therefore, the address counters, data registers, loop counters, and re-initialization of the victim addresses are configured based on physical-layout awareness. In particular, in the data generator, the data register is based on the column multiplexing of the physical layout. The sizes of the counters and the data register are based on the column multiplexing. A logical data generator might not depend on memory topology property such as column multiplexing.

FIG. 8 illustrates an exemplary memory topology for a “1024×18” memory mode having a data width of 18 bits and a physical memory having 4-bit column multiplexing and interleaving. The value inside each cell represents the logical address of the cell mapped to the physical location.

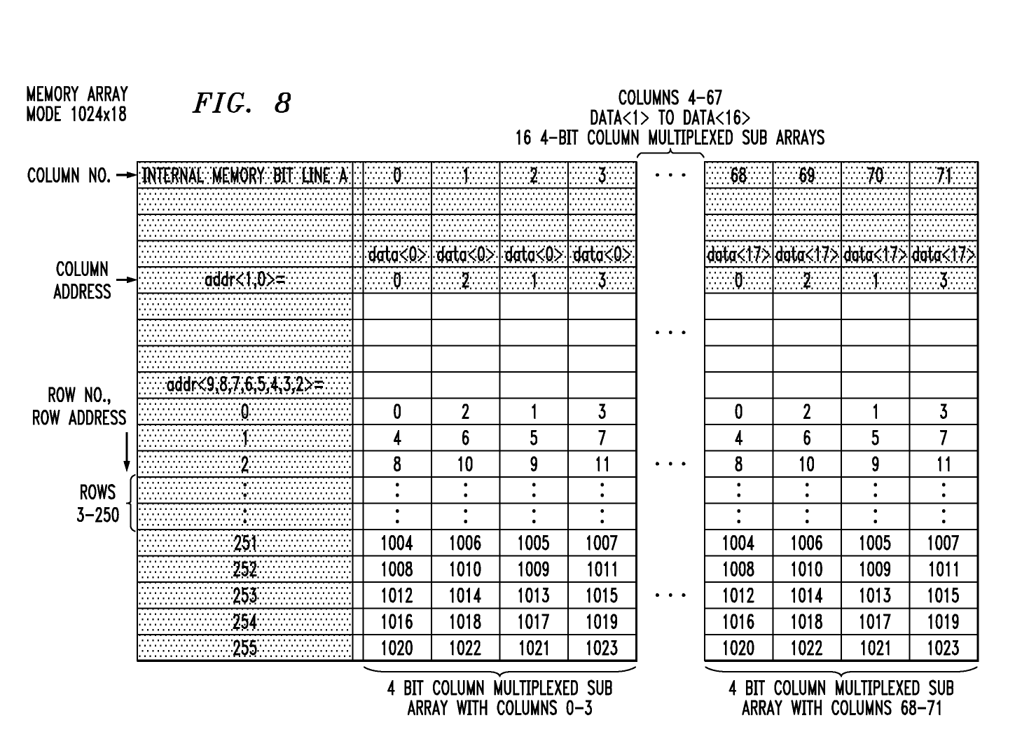

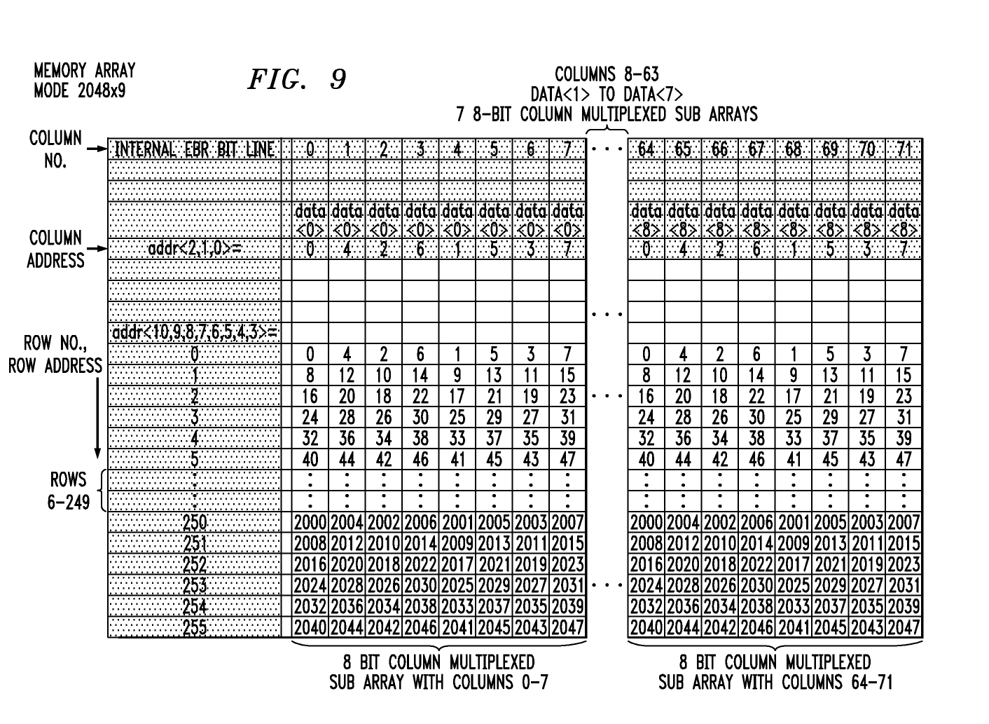

FIG. 9 illustrates an exemplary memory topology for a “2048×9” memory mode having a data width of 9 bits and a physical memory having 8-bit column multiplexing and interleaving. Here, too, the value inside each cell represents the logical address of the cell mapped to the physical location.

FIGS. 8 and 9 illustrate how the same physical location can be mapped to different logical addresses for the different interleaving and column multiplexing of different memory modes.

FIGS. 10 and 11 illustrate in table form the different bit values of register 702 of FIG. 7 for a checkerboard pattern and an inverse checkerboard pattern, respectively.

FIG. 12 illustrates in table form data for data register 702 written in associated memory addresses generated in lockstep by address generator 222 of FIG. 7, where Port A is the aggressor (CW[2]=0) and Port B is the victim (CW[1]=1). FIG. 12 illustrates in table form data for the register of FIG. 7 written in associated memory addresses generated in lockstep by the address generator of FIG. 5.

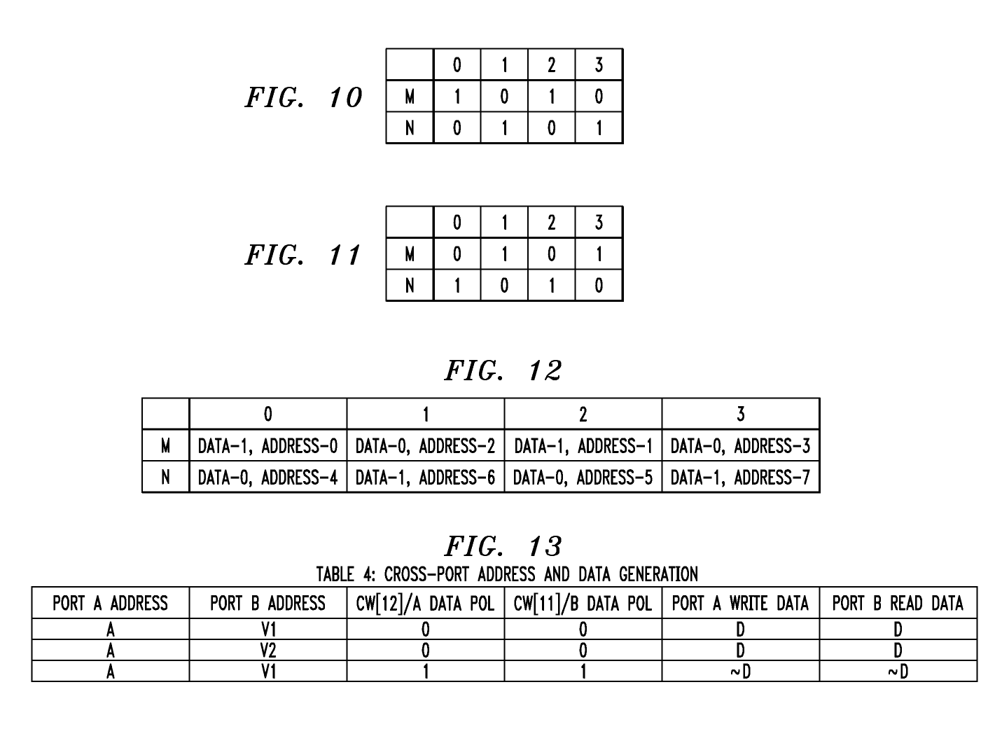

FIG. 13 shows Table 4, which presents exemplary settings for control word bits CW[11:12], where Port A accesses Aggressor Cell A and Port B is one of the Victims V1 or V2. Assuming port A is writing and port B is reading, the settings of CW[11:12] generate the data D and ˜D (i.e., the complement of data D) as needed by the algorithm.

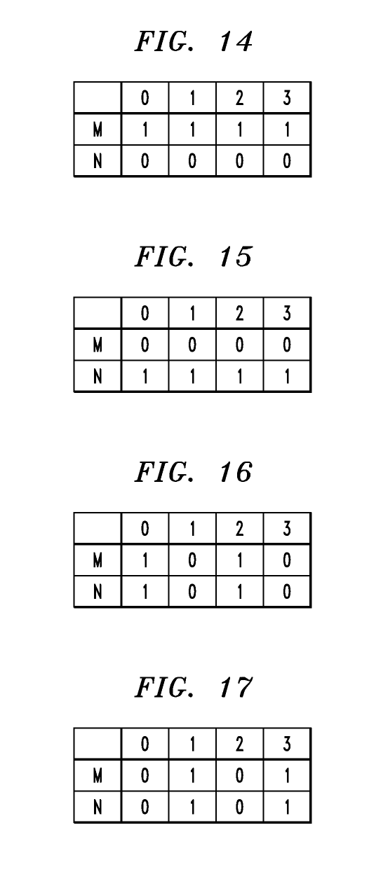

FIGS. 14-17 illustrate in table form the different bit values of register 702 of FIG. 7 for a row stripe pattern, an inverse row stripe pattern, a column stripe pattern, and an inverse column stripe pattern, respectively. In a row stripe pattern, a row of aggressors having values of all 1s has an adjacent row of respective victims either above or below having values of all 0s, and vice versa. Similarly, in a column stripe pattern, a column of aggressors having values of all 1 s has an adjacent column of respective victims either to the left or to the right having values of all 0s, and vice versa.

The BIST approach described previously in this specification uses physical topology information (interleaving, full column-muxing range, etc.) to generate logical addresses and test data for both ports of a dual-port memory for a given mode of memory access during built-in self-testing. Logical addresses are generated so as to access physically adjacent bits (as aggressor-victim pairs). The test data are generated so as to create physical checkerboard, physical row/column stripe, etc., data that the test needs. For a given embedded memory, the physical neighborhoods are fixed and known a priori. The logical neighborhoods are memory mode-dependent; hence, the logical-to-physical mapping changes from mode to mode of memory access. The logical address and test data generators can be configured during testing via control word instructions.

The information about the physical awareness is encoded into each control word that is dynamically loaded into the on-chip BIST circuitry. In the particular implementation shown in FIG. 2, the physical awareness resides in the ATE and is transferred to the on-chip BIST circuitry via a set of control words loaded with the correct instructions for configuring the address and data generators. In alternative implementations, the physical awareness could be implemented elsewhere in the BIST architecture. For example, in another possible implementation, the physical awareness could reside in on-chip ROM (read-only memory) that stores all the control programs for the various modes of operation. A mode signal from the ATE could be employed to select the appropriate control program to execute the desired built-in self-testing with minimal ATE intervention.

### REFERENCES

### Incorporated Herein by Reference in their Entirety

[1] K. Zarrineh and S. J. Upadhyaya, “On Programmable Memory Built-In-Self-Test Architectures,” EDTC '97 Proceedings of the 1997 European Conference on Design and Test, 1997.
[2] A. J. Van de Goor, H. Kukner, and S. Hamdioui, “Optmizing Memory BIST Address Generator Implementations,” 6th International Conference on Design & Technology of Integrated Systems in Nanoscale Era (DTIS), 2011.
[3] R. D. Adams, T. J. Eckenrode, S. L. Gregor, and K. Zarrineh, “Programable multi-port memory BIST with compact microcode,” U.S. Pat. No. 7,168,005 B2, 2007.
[4] M. Nicolaidis and S. Boutobza, “A runtime programmable BIST for testing a multi-port memory,” U.S. Pat. No. 8,042,011 B2, 2011.
[5] K. Chakraborty and P. Mazumder, “A Programmable Boundary Scan Technique for Board-level, Parallel Functional Duplex March Testing of Word-Oriented Multiport Static RAMs,” EDTC '97 Proceedings of the 1997 European Conference on Design and Test, 1997.
[6] K. Truong, “A Simple Built-In Self-Test For Dual Ported SRAMs,” IEEE International Workshop on Memory Technology, Design and Testing, 2000.
[7] D. Youn, T. Kim, and S. Park, “Microcode-based Memory BIST Implementing Modified March Algorithm,”10th Asian Test Symposium, 2001.
[8] I. Voyiatzis, C. Efstathiou, S. Hamdioui, and C. Sgouropoulou, “ALU Based Address Generation for RAMs,” International Conference on Design & Technology of Integrated Systems in Nanoscale Era, 2012.
[9] Y. Park, J. Park, T. Han, and S. Kang, “An Effective Programmable Memory BIST for Embedded Memory,” IEICE TRANS. INF. & SYST., Vol. E92-D, No. 12, December 2009.
[10] N. Q. M. Noor, A. Saparon, and Y. Yusof, “An Overview of Microcode-based and FSM-based Programmable Memory Built-In Self Test (MBIST) Controller for Coupling Fault Detection”, 2009 IEEE Symposium on Industrial Electronics and Applications (ISIEA 2009), Oct. 4-6, 2009, Kuala Lumpur, Malaysia.
[11] N. Q. M. Noor, A. Saparon, and Y. Yusof, “New Microcode's Generation Technique for Programmable Memory Built-In Self Test,” 2010 19^{th} IEEE Asian Test Symposium.
[12] S. K. Jain and C. E. Stroud, “Built-in Self Testing of Embedded Memories,” Design & Test of Computers, IEEE, 1986.
[13] A. Pavlov and M. Sachdev “CMOS SRAM Circuit Design and Parametric Test in Nano-Scaled Technologies: Process-Aware SRAM Design and Test,” Springer, 2008.
[14] K. Chakraborty and P. Mazumder, “New March Tests for Multiport RAM Devices,” Journal of Electronic Testing, 2000.

Embodiments of the invention may be implemented as (analog, digital, or a hybrid of both analog and digital) circuit-based processes, including possible implementation as a single integrated circuit (such as an ASIC or an FPGA), a multi-chip module, a single card, or a multi-card circuit pack. As would be apparent to one skilled in the art, various functions of circuit elements may also be implemented as processing blocks in a software program. Such software may be employed in, for example, a digital signal processor, micro-controller, general-purpose computer, or other processor.

Embodiments of the invention can be manifest in the form of methods and apparatuses for practicing those methods. Embodiments of the invention can also be manifest in the form of program code embodied in tangible media, such as magnetic recording media, optical recording media, solid state memory, floppy diskettes, CD-ROMs, hard drives, or any other non-transitory machine-readable storage medium, wherein, when the program code is loaded into and executed by a machine, such as a computer, the machine becomes an apparatus for practicing the invention. Embodiments of the invention can also be manifest in the form of program code, for example, stored in a non-transitory machine-readable storage medium including being loaded into and/or executed by a machine, wherein, when the program code is loaded into and executed by a machine, such as a computer, the machine becomes an apparatus for practicing the invention. When implemented on a general-purpose processor, the program code segments combine with the processor to provide a unique device that operates analogously to specific logic circuits

Any suitable processor-usable/readable or computer-usable/readable storage medium may be utilized. The storage medium may be (without limitation) an electronic, magnetic, optical, electromagnetic, infrared, or semiconductor system, apparatus, or device. A more-specific, non-exhaustive list of possible storage media include a magnetic tape, a portable computer diskette, a hard disk, a random access memory (RAM), a read-only memory (ROM), an erasable programmable read-only memory (EPROM) or Flash memory, a portable compact disc read-only memory (CD-ROM), an optical storage device, and a magnetic storage device. Note that the storage medium could even be paper or another suitable medium upon which the program is printed, since the program can be electronically captured via, for instance, optical scanning of the printing, then compiled, interpreted, or otherwise processed in a suitable manner including but not limited to optical character recognition, if necessary, and then stored in a processor or computer memory. In the context of this disclosure, a suitable storage medium may be any medium that can contain or store a program for use by or in connection with an instruction execution system, apparatus, or device.

The functions of the various elements shown in the figures, including any functional blocks labeled as “processors,” may be provided through the use of dedicated hardware as well as hardware capable of executing software in association with appropriate software. When provided by a processor, the functions may be provided by a single dedicated processor, by a single shared processor, or by a plurality of individual processors, some of which may be shared. Moreover, explicit use of the term “processor” or “controller” should not be construed to refer exclusively to hardware capable of executing software, and may implicitly include, without limitation, digital signal processor (DSP) hardware, network processor, application specific integrated circuit (ASIC), field programmable gate array (FPGA), read only memory (ROM) for storing software, random access memory (RAM), and non volatile storage. Other hardware, conventional and/or custom, may also be included. Similarly, any switches shown in the figures are conceptual only. Their function may be carried out through the operation of program logic, through dedicated logic, through the interaction of program control and dedicated logic, or even manually, the particular technique being selectable by the implementer as more specifically understood from the context.

It should be appreciated by those of ordinary skill in the art that any block diagrams herein represent conceptual views of illustrative circuitry embodying the principles of the invention. Similarly, it will be appreciated that any flow charts, flow diagrams, state transition diagrams, pseudo code, and the like represent various processes which may be substantially represented in computer readable medium and so executed by a computer or processor, whether or not such computer or processor is explicitly shown.

Unless explicitly stated otherwise, each numerical value and range should be interpreted as being approximate as if the word “about” or “approximately” preceded the value or range.

It will be further understood that various changes in the details, materials, and arrangements of the parts which have been described and illustrated in order to explain embodiments of this invention may be made by those skilled in the art without departing from embodiments of the invention encompassed by the following claims.

In this specification including any claims, the term “each” may be used to refer to one or more specified characteristics of a plurality of previously recited elements or steps. When used with the open-ended term “comprising,” the recitation of the term “each” does not exclude additional, unrecited elements or steps. Thus, it will be understood that an apparatus may have additional, unrecited elements and a method may have additional, unrecited steps, where the additional, unrecited elements or steps do not have the one or more specified characteristics.

The use of figure numbers and/or figure reference labels in the claims is intended to identify one or more possible embodiments of the claimed subject matter in order to facilitate the interpretation of the claims. Such use is not to be construed as necessarily limiting the scope of those claims to the embodiments shown in the corresponding figures.

It should be understood that the steps of the exemplary methods set forth herein are not necessarily required to be performed in the order described, and the order of the steps of such methods should be understood to be merely exemplary. Likewise, additional steps may be included in such methods, and certain steps may be omitted or combined, in methods consistent with various embodiments of the invention.

Although the elements in the following method claims, if any, are recited in a particular sequence with corresponding labeling, unless the claim recitations otherwise imply a particular sequence for implementing some or all of those elements, those elements are not necessarily intended to be limited to being implemented in that particular sequence.

Reference herein to “one embodiment” or “an embodiment” means that a particular feature, structure, or characteristic described in connection with the embodiment can be included in at least one embodiment of the invention. The appearances of the phrase “in one embodiment” in various places in the specification are not necessarily all referring to the same embodiment, nor are separate or alternative embodiments necessarily mutually exclusive of other embodiments. The same applies to the term “implementation.”

The embodiments covered by the claims in this application are limited to embodiments that (1) are enabled by this specification and (2) correspond to statutory subject matter. Non-enabled embodiments and embodiments that correspond to non-statutory subject matter are explicitly disclaimed even if they fall within the scope of the claims.

1. An integrated circuit comprising built-in self-test (BIST) circuitry for multiport memory, the BIST circuitry comprising:
a configurable address generator that can be configured to concurrently generate first and second logical memory addresses corresponding to physically neighboring first and second memory cells of the multiport memory for a selected memory mode; and
a configurable data generator that can be configured to concurrently generate first and second sets of data for the selected memory mode, such that:
the first set of data is written into and read from the multiport memory via a first memory port using the first logical memory address; and
the second set of data is written into and read from the multiport memory via a second memory port using the second logical memory address.

2. The invention of claim 1, wherein the multiport memory is embedded memory within the integrated circuit.

3. The invention of claim 1, wherein the selected memory mode is one of at least two of available memory modes having a different numbers of bits for each corresponding set of data.

4. The invention of claim 1, wherein the configurable address and data generators are configured to implement built-in self-testing for the selected memory mode based on a sequence of control words, each control word corresponding to a different march operation of the built-in self-testing.

5. The invention of claim 4, wherein the BIST circuitry further comprises a program store configured to store the sequence of control words.

6. The invention of claim 4, wherein the sequence of control words is provided to the BIST circuitry by off-chip automatic test equipment (ATE).

7. The invention of claim 1, wherein the address generator comprises column and row incrementers/decrementers and multiplexers configured to generate the first and second logical memory addresses for the physically neighboring first and second memory cells even when the first and second logical memory addresses are not logically adjacent in the selected memory mode.

8. The invention of claim 1, wherein the data generator comprises multiplexers configured to generate desired data patterns for the physically neighboring first and second memory cells even when the first and second logical memory addresses for those memory cells are not logically adjacent in the selected memory mode.

9. The invention of claim 1, wherein the integrated circuit is a field-programmable gate array.

10. The invention of claim 1, wherein:
the multiport memory is embedded memory within the integrated circuit;
at least two memory modes are available each having a different numbers of bits for each corresponding set of data;
the configurable address and data generators are configured to implement built-in self-testing for the selected memory mode based on a sequence of control words, each control word corresponding to a different march operation of the built-in self-testing;
the BIST circuitry further comprises a program store configured to store the sequence of control words;
the sequence of control words is provided to the BIST circuitry by off-chip automatic test equipment (ATE);
the address generator comprises column and row incrementers/decrementers and multiplexers configured to generate the first and second logical memory addresses for the physically neighboring first and second memory cells even when the first and second logical memory addresses are not logically adjacent in the selected memory mode; and
the data generator comprises multiplexers configured to generate desired data patterns for the physically neighboring first and second memory cells even when the first and second logical memory addresses for those memory cells are not logically adjacent in the selected memory mode.

11. The invention of claim 10, wherein the integrated circuit is a field-programmable gate array.

12. The invention of claim 1, wherein the selected memory mode is one of a plurality of available memory modes having different column-multiplexing schemes.

13. An integrated circuit comprising built-in self-test (BIST) circuitry for multiport memory, the BIST circuitry comprising:
a configurable address generator that can be configured to generate first and second logical memory addresses corresponding to physically neighboring first and second memory cells of the multiport memory for a selected memory mode of a plurality of available memory modes having different column-multiplexing schemes; and
a configurable data generator that can be configured to generate first and second sets of data for the selected memory mode, such that:
the first set of data is written into and read from the multiport memory via a first memory port using the first logical memory address; and
the second set of data is written into and read from the multiport memory via a second memory port using the second logical memory address.

14. The invention of claim 13, wherein the configurable address generator can be configured to concurrently generate the first and second logical memory addresses.

15. The invention of claim 13, wherein the configurable data generator can be configured to concurrently generate the first and second sets of data.

16. The invention of claim 13, wherein the integrated circuit is a field-programmable gate array.

17. An integrated circuit comprising built-in self-test (BIST) circuitry for multiport memory, the BIST circuitry comprising:
a configurable address generator that can be configured to generate first and second logical memory addresses corresponding to first and second memory cells of the multiport memory for a selected memory mode of a plurality of available memory modes having different column-multiplexing schemes; and
a configurable data generator that can be configured to generate first and second sets of data for the selected memory mode, such that:
the first set of data is written into and read from the multiport memory via a first memory port using the first logical memory address; and
the second set of data is written into and read from the multiport memory via a second memory port using the second logical memory address.

18. The invention of claim 17, wherein the integrated circuit is a field-programmable gate array.

19. The invention of claim 17, wherein the first and second memory cells are physically neighboring cells.

20. The invention of claim 17, wherein:
the configurable address generator can be configured to concurrently generate the first and second logical memory addresses; and
the configurable data generator can be configured to concurrently generate the first and second sets of data.
